(19) United States
(12) Patent Application Publication
(10) Pub. No.: US 2019/0146216 A1
(43) Pub. Date: May 16, 2019

(54) DUAL-SIDED TRANSPARENT DISPLAY ASSEMBLIES WITH NON-TRANSPARENT CIRCUITS

(71) Applicant: GM Global Technology Operations LLC, Detroit, MI (US)

(72) Inventors: Julien P. Mourou, Bloomfield Hills, MI (US); Spencer W. Chamberlain, Sterling Heights, MI (US); Louise E. Stauffer, Bloomfield Hills, MI (US); James A. Carpenter, Rochester Hills, MI (US)

(73) Assignee: GM Global Technology Operations LLC, Detroit, MI (US)

(21) Appl. No.: 15/812,324

(22) Filed: Nov. 14, 2017

(51) Int. Cl. G02B 27/01; H01L 25/075; B60J 1/02; B60K 35/00

(52) U.S. Cl. CPC G02B 27/0101; H01L 25/0753; G02F 1/133305; B60K 35/00; G02B 2027/014; B60J 1/02

(57) ABSTRACT

Disclosed are dual-sided transparent display assemblies, methods for making/using such transparent display assemblies, and motor vehicles with a window unitarily formed with a dual-sided, laminated-glass transparent display unit. A representative dual-sided transparent electronic display device includes first and second rigid transparent layers juxtaposed in opposing, spaced face-to-face relation with each other. Adhesive layers are positioned on the interior surfaces of these rigid transparent layers. First and second display circuits are attached via the adhesive layers to the first and second rigid transparent layers, respectively. Each display circuit includes a discrete array of electronically-activated light elements. The electronic display device also includes a flexible substrate with a first surface mounting thereon the first circuit and an opposing second surface mounting thereon the second circuit. The flexible substrate is fabricated with a plurality of apertures, such as through holes and/or slots, interleaved with the first and second arrays of electronically-activated light elements.

### INTRODUCTION

The present disclosure relates generally to electronic display devices with transparent display capabilities. More specifically, aspects of this disclosure relate to a laminated-glass transparent display unit for a vehicle windshield, rear window or back glass, side door windows, etc.

Most current production motor vehicles, such as the modern-day automobile, are erected on a rigid vehicle body—either as a body-on-frame or a unibody construction—with an interior passenger compartment that seats and safeguards the vehicle occupants. In automotive applications, driver-side and passenger-side door assemblies are movably mounted to port and starboard flanks of the vehicle body to provide controlled access for entering and exiting the vehicle, and to provide lateral visibility through accompanying door windows. A rear window (coupes and sedans) or back glass (trucks and SUVs) seals off, yet provides visibility through, a rearward end of the passenger compartment. Mounted between the forward A-pillars of the vehicle body is a windshield (or “windscreen” in some countries) that prevents the unwanted ingress of wind, rain, and debris, and provides an aerodynamically formed window through which the driver views the roadway. Modern windshields, side and rear windows, and glass panel roofs are generally formed as a laminated glass construction—a multi-layer assembly with a plastic interlayer, typically of polyvinyl butyral (PVB) or ethylene-vinyl acetate (EVA), which is laminated between two or more curved sheets of tempered glass.

To help increase driver awareness of vehicle systems operation and ambient driving conditions, some modern vehicles supplement the dashboard instrument panel and the center console touchscreen display with a heads-up display (HUD) device that projects light onto an aft surface of the front windshield to create a viewable display of information. Alternative HUD configurations employ a dashboard-mounted “see through” display device, which employs light emitting diode (LED) or liquid crystal display (LCD) technologies to provide fully or partially transparent display capabilities. Irrespective of which technique is employed, an automotive HUD is designed to present information within the operator's forward-driving field of view and, thus, reduce superfluous eye scanning and glance behavior at the instrument panel and center console. HUDs also help to ameliorate eye strain resulting from repeated pupillary light reflex caused by light changes when shifting views between the interior and exterior of the vehicle, and strain resulting from frequent refocusing of the eyes to shift views between optically near instruments and optically distant vehicles, road conditions, etc.

### SUMMARY

Disclosed herein are dual-sided transparent display assemblies, methods for making and methods for using such transparent display assemblies, and motor vehicles with a vehicle windshield, rear window or back glass, door window, or other vehicle glass, that is unitarily formed with a dual-sided, laminated-glass transparent display unit. By way of example, there is presented a transparent electronic display device with non-transparent light emissive circuits (e.g., LED, LCD, etc.) mounted onto a flexible substrate fabricated with through holes or slots of sufficient size and shape to enable approximately 20% to 50% transparency. For automotive applications, a flexible glass or polymeric substrate and light emissive elements are adhered between two panes of treated glass to form a shatter-resistant laminated glass unit. Flexible circuit material and the devices mounted on these circuits are not transparent; yet, the size and placement of the holes/slots allow the display unit to be perceived as see through. This architecture offers an automotive-grade exterior/interior transparent display that is operable to communicate with the vehicle occupants as well as pedestrians, cyclists, and neighboring vehicles, while allowing occupants to look out of the vehicle. The display unit may be optionally tuned to generate an “opera lamp” proximate the B-pillar or C-pillar during vehicle motion, e.g., with an intensity of approximately 70 nits (candela per square meter) and a transparency of at least 20%.

Aspects of this disclosure are directed to dual-sided transparent display assemblies with non-transparent circuits. For instance, an electronic display device is presented that includes a first (interior) rigid transparent layer and a second (exterior) rigid transparent layer, where the two rigid transparent layers are juxtaposed in opposing spaced relation with each other. The first and second rigid transparent layers, which may be in the nature of tempered glass panels, include interior surfaces that face each other. A respective adhesive layer is positioned on the interior surface of each rigid transparent layer. A first display circuit is attached to the first rigid transparent layer's interior surface via one of the adhesive layers, while a second display circuit is attached to the second rigid transparent layer's interior surface via the other one of the adhesive layers. Each display circuit includes a discrete array of electronically-activated light elements, which may be in the nature of LED or LCD cells. The electronic display device also includes a flexible substrate with a first surface mounting thereon the first display circuit and a second surface, opposite the first, mounting thereon the second display circuit. The flexible substrate, which may be fabricated from flexible glass or elastic thermoplastic resin polymer, defines therethrough multiple apertures, such as through holes or slots, that are interleaved with the first and second arrays of electronically-activated light elements to thereby provide a predetermined level of visual transparency.

Other aspects of the present disclosure are directed to motor vehicles equipped with at least one vehicle window that is unitarily formed with a dual-sided, laminated-glass transparent display unit. As used herein, the term “motor vehicle” may include any relevant vehicle platform, such as passenger vehicles (internal combustion engine, hybrid electric, full electric, fuel cell electric, fully or partially autonomous, etc.), commercial vehicles, industrial vehicles, tracked vehicles, off-road and all-terrain vehicles (ATV), farm equipment, boats, airplanes, etc. A motor vehicle is presented that includes a vehicle body with a passenger compartment terminating at a forward end thereof at a front window frame, which is defined, at least in part, by a pair of A-pillars. Multiple road wheels are rotatably attached to the vehicle body and driven, for example, by an engine and/or an electric motor.

Mounted within the front window frame of the vehicle, between the two A-pillars, is a front windshield unit fabricated with an integral electronic display device. The unitary front windshield/display unit includes a pair of rigid glass layers that are juxtaposed in opposing, face-to-face spaced relation with each other. Adhesive layers are positioned on the interior surfaces of the two rigid glass layers. A first display circuit is attached to the interior surface of one of the rigid glass layers via one of the adhesive layers, whereas a second display circuit is attached to the interior surface of the other rigid glass layer via another one of the adhesive layers. Each display circuit includes a discrete array of electronically-activated LED elements. A flexible substrate mounts on a first surface thereof the first display circuit, and mounts on an opposing second surface thereof the second display circuit. This flexible substrate defines therethrough a pattern of apertures interleaved with the first and second arrays of electronically-activated light elements.

Additional aspects of this disclosure are directed to methods for manufacturing and methods for using any of the herein depicted or described dual-sided transparent display assemblies. For instance, a method is presented for assembling an electronic display device. The representative method includes, in any order and in any combination with any of the disclosed features and options: providing first and second rigid transparent layers juxtaposed in opposing spaced relation with each other, the first rigid transparent layer including a first interior surface, and the second rigid transparent layer including a second interior surface facing the first interior surface; applying a first adhesive layer on the first interior surface of the first rigid transparent layer; applying a second adhesive layer on the second interior surface of the second rigid transparent layer; attaching a first display circuit to the first rigid transparent layer via the first adhesive layer, the first display circuit including a first array of electronically-activated light elements; attaching a second display circuit to the second rigid transparent layer via the second adhesive layer, the second display circuit including a second array of electronically-activated light elements; and, mounting the first and second display circuits to opposing first and second surfaces, respectively, of a flexible substrate, the flexible substrate defining therethrough a plurality of apertures interleaved with the first and second arrays of electronically-activated light elements.

The above summary is not intended to represent every embodiment or every aspect of the present disclosure. Rather, the foregoing summary merely provides an exemplification of some of the novel concepts and features set forth herein. The above features and advantages, and other features and advantages, will be readily apparent from the following detailed description of illustrated embodiments and representative modes for carrying out the disclosure when taken in connection with the accompanying drawings and appended claims. Moreover, this disclosure expressly includes any and all combinations and subcombinations of the elements and features presented above and below.

### BRIEF DESCRIPTION OF THE DRAWINGS

FIG. 1 is a forward-facing perspective-view illustration of a portion of a representative motor vehicle passenger compartment with a unitary windshield with integral dual-sided, laminated-glass transparent display device in accordance with aspects of the present disclosure.

FIG. 2 is a schematic side-view schematic illustration of the representative windshield/transparent display unit of FIG. 1.

FIGS. 3A-3D are front-view illustrations of representative flexible substrate through-hole configurations, including square holes with a triangular pitch (FIG. 3A), circular holes with a square pitch (FIG. 3B), circular holes with a triangular pitch (FIG. 3C), and hexagonal holes with a triangular pitch (FIG. 3D).

The present disclosure is amenable to various modifications and alternative forms, and some representative embodiments have been shown by way of example in the drawings and will be described in detail herein. It should be understood, however, that the novel aspects of this disclosure are not limited to the particular forms illustrated in the appended drawings. Rather, the disclosure is to cover all modifications, equivalents, combinations, subcombinations, permutations, groupings, and alternatives falling within the scope of this disclosure as defined by the appended claims.

### DETAILED DESCRIPTION

This disclosure is susceptible of embodiment in many different forms. There are shown in the drawings and will herein be described in detail representative embodiments of the disclosure with the understanding that these illustrated examples are provided as an exemplification of the disclosed principles, not limitations of the broad aspects of the disclosure. To that extent, elements and limitations that are described, for example, in the Abstract, Summary, and Detailed Description sections, but not explicitly set forth in the claims, should not be incorporated into the claims, singly or collectively, by implication, inference or otherwise.

For purposes of the present detailed description, unless specifically disclaimed: the singular includes the plural and vice versa; the words “and” and “or” shall be both conjunctive and disjunctive; the word “all” means “any and all”; the word “any” means “any and all”; and the words “including” and “comprising” and “having” mean “including without limitation.” Moreover, words of approximation, such as “about,” “almost,” “substantially,” “approximately,” and the like, may be used herein in the sense of “at, near, or nearly at,” or “within 0-5% of,” or “within acceptable manufacturing tolerances,” or any logical combination thereof, for example. Lastly, directional adjectives and adverbs, such as fore, aft, inboard, outboard, starboard, port, vertical, horizontal, upward, downward, front, back, left, right, etc., may be with respect to a motor vehicle, such as a forward driving direction of a motor vehicle when the vehicle is operatively oriented on a normal driving surface, for example.

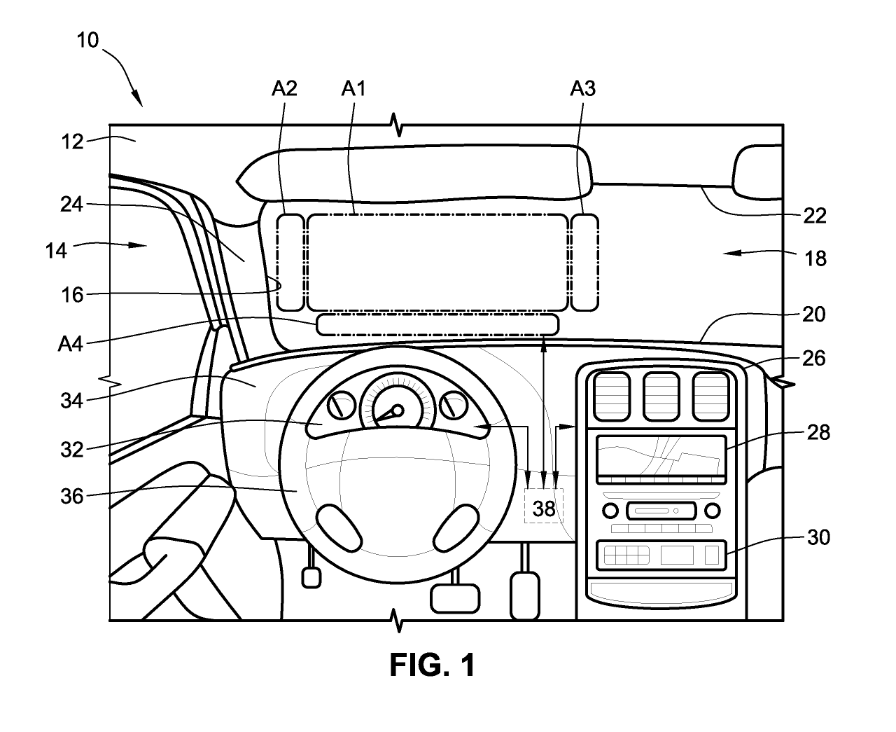

Referring now to the drawings, wherein like reference numbers refer to like features throughout the several views, there is shown in FIG. 1 a perspective-view illustration of a representative automobile, which is designated generally at 10 and portrayed herein for purposes of discussion as a sport utility vehicle (SUV) type passenger vehicle. Mounted to the vehicle body 12 of the automobile 10, e.g., at a forward end of a passenger compartment 14 within a front window frame 16, is a front windshield unit with integral dual-sided, laminated-glass transparent display device (designated generally at 18 in FIG. 1). The illustrated automobile 10—also referred to herein as “motor vehicle” or “vehicle” for short—is merely an exemplary application with which aspects and features of this disclosure may be practiced. In the same vein, implementation of the present concepts into a front windshield unit 18 should also be appreciated as an exemplary application of the novel concepts disclosed herein. As such, it will be understood that aspects and features of the present disclosure may be applied to other vehicle glass (e.g., rear windows and back glass, side door windows, vent glass, quarter glass, sunroofs, moonroofs, etc.), utilized for any logically relevant type of motor vehicle, and implemented for both automotive and non-automotive applications alike. Lastly, the drawings presented herein are not necessarily to scale and are provided purely for instructional purposes. Thus, the specific and relative dimensions shown in the drawings are not to be construed as limiting.

Front windshield unit with integral dual-sided, laminated-glass transparent display device 18 (also referred to as “front windshield unit” or “electronic display device” for brevity) may be configured as an Enhanced Vision System (EVS) that is operable to dynamically display and dynamically update graphical images upon a window of a subject vehicle to present vehicle-related and non-vehicle-related information of various forms, including vehicle systems operation, ambient driving conditions, infotainment features, personalized occupant-specific data, etc. In accord with the illustrated example, the front windshield unit 18 is sealingly fastened, e.g., via a bonding agent and a window gasket or polymeric weather stripping (not shown), to the front window frame 16. A lower edge of the front window frame 16 is delineated by a dash panel cowl 20, whereas an upper edge is delineated by a roof rail 22, and the two lateral edges are delineated by a pair of A-pillars 24 (only one of which is visible; a second mirrored counterpart is located on the opposite side of the window frame 16). Also present within the vehicle passenger compartment 14 is a center stack 26 that is equipped with a human-machine interface (HMI) in the form of an electronic touchscreen video display 28 and a button panel 30. Touchscreen video display 28 is operable to receive user inputs and display image, text, and video-based content. A digital instrument panel (IP) 32, which is housed within a front dashboard 34 forward of a steering wheel 36, displays gauges, instrumentation, and controls for monitoring and regulating selected operations of the vehicle 10.

The front windshield unit 18, electronic touchscreen video display 28, button panel 30, and digital IP 32 communicate—wired or wirelessly—with a programmable electronic control unit (ECU) 38. Vehicle ECU 38 may systematically monitor various sensors, system components, and/or other relevant inputs, both manual and automated, and identify information based on these monitored inputs that will be relayed to the vehicle occupants or to passing pedestrians, vehicles, etc., and determine a graphical representation of the selected information. This ECU 38 may communicate directly with various systems, subsystems, and components, or the ECU 38 may alternatively or additionally communicate over a distributed computing network, such as a LAN/CAN system, a satellite system, the Internet, etc. Various vehicle sensors may be prompted to monitor vehicle speed, engine speed, transmission state, engine coolant temperature, fuel level and economy, oil level, tire pressure, wheel slip, battery state-of-charge (SOC), mileage, navigation information, and/or any other parameters representative of vehicle operation. Only select components of the vehicle 10 have been shown and will be described in detail herein; nevertheless, the vehicle 10 may include additional and alternative features, and other peripheral components, for example, for carrying out the various operations and functions disclosed herein.

Front windshield unit 18 functions as both an aerodynamic, shatter-resistant windscreen as well as a dual-sided, see-through HUD device. As a dual-sided display device, the front windshield unit 18 is capable of selectively displaying a first set of images superimposed within an occupant's forward-facing field of view through the front windshield 18, and selectively displaying a second set of images, similar or distinct from the first, that are readily decipherable by persons outside of the vehicle 10. To provide “see through” functionality, the front windshield unit 18 remains sufficiently transparent to allow occupants of the vehicle 10 to clearly see objects outside of the passenger compartment 14 through the front windshield 18 while the first and/or second sets of images are being displayed. In this regard, the front windshield unit 18 of FIG. 1 presents four transparent display areas A1-A4, each of which is configured, as explained below, to display an image within discrete segments of a driver's field of vision. It is certainly within the scope and spirit of this disclosure for the front windshield unit 18 to provide greater or fewer transparent display areas, any or all of which may comprise differing shapes, sizes, and/or locations from that shown in the drawings. For instance, all or substantially all of the visible surface area of the front windshield unit 18 (i.e., that which is exposed within the inner perimeter of the front window frame 16) may be operable as a transparent display area. An EVS graphics engine, embodied as a dedicated software application or a discrete control module within the ECU 38, for example, includes display software or processor-executable code that translates data and user requests into graphical representations of desired information.

As indicated above, ECU 38 is constructed and programmed to govern, among other things, operation of the front windshield unit 18, electronic touchscreen display 28, button panel 30, and digital IP 32. Control module, module, controller, control unit, electronic control unit, processor, and any permutations thereof may be defined to mean any one or various combinations of one or more of logic circuits, Application Specific Integrated Circuit(s) (ASIC), electronic circuit(s), central processing unit(s) (e.g., microprocessor(s)), and associated memory and storage (e.g., read only, programmable read only, random access, hard drive, tangible, etc.)), whether resident, remote or a combination of both, executing one or more software or firmware programs or routines, combinational logic circuit(s), input/output circuit(s) and devices, appropriate signal conditioning and buffer circuitry, and other components to provide the described functionality. Software, firmware, programs, instructions, routines, code, algorithms and similar terms may be defined to mean any controller executable instruction sets including calibrations and look-up tables. The ECU may be designed with a set of control routines executed to provide the desired functions. Control routines are executed, such as by a central processing unit, and are operable to monitor inputs from sensing devices and other networked control modules, and execute control and diagnostic routines to control operation of devices and actuators. Routines may be executed at in real-time, continuously, systematically, sporadically and/or at regular intervals, for example, each 100 microseconds, 3.125, 6.25, 12.5, 25 and 100 milliseconds, etc., during ongoing vehicle use or operation. Alternatively, routines may be executed in response to occurrence of an event during operation of the vehicle 10.

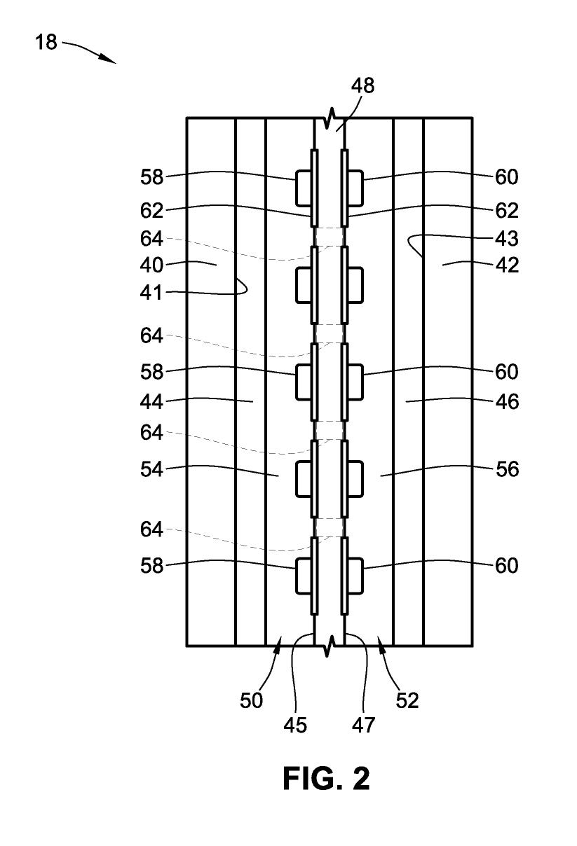

FIG. 2 schematically illustrates the front windshield unit 18 with dual-sided transparent display capabilities of FIG. 1. In accord with the illustrated example, the front windshield unit 18 is a multi-layer composite construction composed of at least five layers: first and second rigid transparent layers 40 and 42, respectively; first and second adhesive layers 44 and 46, respectively; and a central backing layer 48 (also referred to herein as “flexible substrate”) supporting thereon first and second display circuits 50 and 52, respectively. In at least some embodiments, the foregoing layers 40, 42, 44, 46, 48 are coextensive with and, thus, span substantially the entirety of one another; alternatively, one or more layers may take on distinctive shapes or sizes. It is further contemplated that the composite construction may comprise additional or fewer layers than the five layers enumerated above. As an example, first and second insulating layers 54 and 56, respectively, may be interposed between the adhesive layers 44, 46 and the flexible substrate 48. Other optional or alternative layers may include, singly, collectively or in any combination, a switchable tint glass (“auto shading”) layer, a windshield heat strip (“defroster”) layer, an anti-glare layer, an ultraviolet (UV)/infrared (IR) blocking layer, etc. It should also be noted that the use of the term “layer” in the description and claims, while inclusive of, does not necessarily require that a particular segment of the composite construction be a continuous sheet or otherwise span the entirety of all remaining layers unless otherwise explicitly stated.

With continuing reference to FIG. 2, the first and second rigid transparent layers 40, 42 may be positioned as the outermost layers of the front windshield unit 18, thus sandwiching therebetween the remaining layers 44, 46, 48, 54, 56 and display circuits 50, 52. Juxtaposed in opposing spaced relation with each other, the first rigid transparent layer 40 includes a first interior surface 41 that faces a second interior surface 43 of the second rigid transparent layer 42. According to the illustrated architecture, the central backing layer 48 in FIG. 2 is the middle-most layer of the front windshield unit 18, located between the two insulating layers 54, 56. Insulating layers 54, 56, in turn, are located between the two adhesive layers 44, 46, with the first insulating layer 54 sandwiched between the central backing layer 48 and the first adhesive layer 44, and the second insulating layer 56 sandwiched between the central backing layer 48 and the second adhesive layer 46. Moreover, the two adhesive layers 44, 46 are located between the rigid transparent layers 40, 42, with the first adhesive layer 44 applied on the first interior surface 41 of the first transparent layer 40 and the second adhesive layer 46 applied on the second interior surface 43 of the second transparent layer 42. The first and second rigid transparent layers 40, 42 may be individually fabricated from any suitably rigid and transparent material, including glass panels, high-impact polycarbonate or acrylic panels, and the like. In contrast, the first and second adhesive layers 44, 46 may comprise any suitable laminate and adhesive materials, including polyvinyl butyral (PVB) materials, ethylene copolymer materials, and other hot melt adhesives, as some non-limiting examples.

The front windshield unit's first display circuit 50, which may drive displayed information for a user or other entity outside the vehicle 10, is mounted onto a first surface 45 of the flexible substrate 48. Conversely, the second display circuit 52, which may drive displayed information for one or more users inside the vehicle 10, is mounted onto a second surface 47 of the flexible substrate 48, on the opposite side of the first surface 45. It may be desirable, for at least some implementations, that the flexible substrate 48 be fabricated from a transparent or semi-transparent bendable glass material, such as fusion-drawn conformable glass panel with a Young's Modulus of at least 60 GPa and a bend radius of at least 80 mm. Alternatively, the flexible substrate 48 may be fabricated from an opaque or otherwise non-transparent thermoplastic resin material, such as an elastic polyethylene terephthalate (PET) panel. Mounting of the individual display circuits 50, 52 may include a suitable manufacturing technique, including masking, vapor deposition, and screen printing techniques for glass.

First display circuit 50 is either directly or indirectly attached to the first rigid transparent layer 40 via the first adhesive layer 44, whereas the second display circuit 52 is directly or indirectly attached to the second rigid transparent layer 42 via the second adhesive layer 46. In instances of indirect attachment, such as that shown in FIG. 2, the display circuits 50, 52 may be partially or fully encapsulated within their respective insulating layers 54, 56. As an example, each insulating layer 54, 56 may be fabricated as a plastic polyamide (PI) coverlay film that is laminated onto or otherwise applied on top of the display circuits 50, 52, e.g., and coated by an optional modified stage-B acrylic or epoxy adhesive. The first display circuit 50 is generally composed of a discrete (first) array of electronically-activated light elements 58, and the second display circuit 52 is generally composed a discrete (second) array of electronically-activated light elements 60. Each array of electronically-activated light elements 58, 60 may comprise a predetermined pattern of light emitting diode (LED) cells or liquid crystal display (LCD) cells, including variants and combinations thereof (e.g., OLED, AMOLED, TFT-LCD, etc.). In general, these display circuits 50, 52, including their corresponding light elements 58, 60, interconnecting electric traces, complementary circuit devices, etc., have little or no transparency. For instance, each circuit may include elements fabricated from indium tin oxide, silver, gold, platinum, graphene, copper, and/or glass deposited circuit features. In at least some embodiments, each electronically-activated light element 58, 60 is deposited on a Printed Circuit Board (PCB) 62, typically of PET plastic with copper deposit, which may then be adhered to the central backing layer 48.

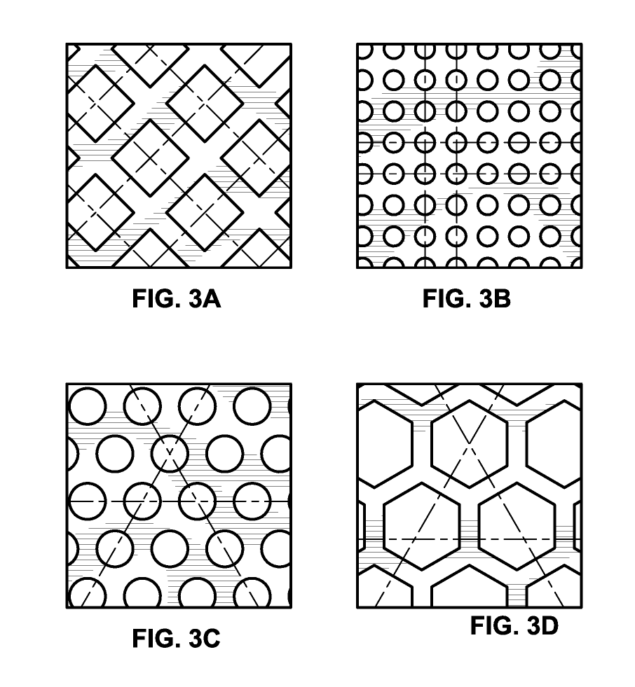

Transparency during the single-sided and dual-sided display of images via the electronically-activated light elements 58, 60 of the front windshield unit 18 is achieved, at least in part, by arranging the various elements of the display circuits 50, 52 within semi-transparent or opaque regions of the central backing layer 48 and concomitantly allowing a user to see through a pattern of cavities on, in, or through the flexible substrate 48. Flexible substrate 48 of FIG. 2 is shown formed, machined, or otherwise fabricated with multiple apertures 64 that are interleaved with the first and second arrays of electronically-activated light elements 58, 60. It is contemplated that these apertures 64 take on an innumerable combination of shapes, sizes, and arrangements, including slots (FIG. 2) and through holes (FIGS. 3A-3D). It is desirable, for at least some configurations, that these apertures 64 have a predetermined size, geometry, concentration and arrangement that cooperatively provide a visible transparency of at least approximately 20% to 50%. Through holes with a diameter of about 1.5 mm and a pitch of approximately 2.5 mm provide a transparency of approximately 50%, for example. This example may include 200-micron (or less) LEDs that are tightly spaced (e.g., every 60-65 microns). As used herein, the term “pitch” may be defined to include the shortest center-to-center distance between immediately adjacent apertures. As used herein, the term “square pitch” may be defined to require the apertures be arranged in a square pattern such that bisecting rectilinear centerlines connecting adjacent apertures form a right regular quadrilateral, e.g., as exemplified in FIGS. 3A and 3B. By comparison, the term “triangular pitch”, as used herein, may require the apertures be arranged in a triangular pattern such that bisecting rectilinear centerlines connecting adjacent apertures form an equilateral triangle, e.g., as exemplified in FIGS. 3C and 3D.

The apertures 64 of the flexible substrate 48 may consist of circular through holes with a diameter of approximately 1 mm to 6 mm and a pitch of approximately 2 mm to 10 mm. FIG. 3B, for example, illustrates a transparency pattern with circular holes of a first size (e.g., a diameter of approximately 1.5-2.5 mm) arranged with a square pitch (e.g., of approximately 4-6 mm). Comparatively, FIG. 3C illustrates a transparency pattern with circular holes of a second size (e.g., diameter of approximately 2-5 mm) arranged with a triangular pitch (e.g., of approximately 3.5-8 mm). As another option, the apertures 64 of the flexible substrate 48 may consist of square through holes with a width of approximately 1 mm to 12 mm and a pitch of approximately 5 mm to 20 mm. FIG. 3A, for example, illustrates a transparency pattern with square holes of a third size (e.g., width of approximately 5-10 mm) arranged with a square pitch (e.g., approximately 8-15 mm). As yet another option, the apertures 64 of the flexible substrate 48 may consist of polygonal through holes with a major dimension of approximately 2 mm to 11 mm and a pitch of approximately 4 mm to 14 mm. FIG. 3D, for example, illustrates a transparency pattern with hexagonal through holes that are approximately 11 mm at their widest point and set with a triangular pitch of approximately 14 mm. It is envisioned that the apertures 64 of the flexible substrate 48 include a combination of differently shaped apertures, including any of those described above and illustrated in the drawings. Moreover, the apertures 64 may take on any other regular, irregular, any non-conventional geometries within the scope of this disclosure. These apertures 64 may be pre-formed into the flexible substrate 48, or may be machined using any suitable technique, including die cut, laser cut, or any other standard practice for cutting holes.

Aspects of the present disclosure have been described in detail with reference to the illustrated embodiments; those skilled in the art will recognize, however, that many modifications may be made thereto without departing from the scope of the present disclosure. The present disclosure is not limited to the precise construction and compositions disclosed herein; any and all modifications, changes, and variations apparent from the foregoing descriptions are within the scope of the disclosure as defined by the appended claims. Moreover, the present concepts expressly include any and all combinations and subcombinations of the preceding elements and features.

What is claimed:

1. An electronic display device, comprising:
first and second rigid transparent layers juxtaposed in opposing spaced relation with each other, the first rigid transparent layer including a first interior surface, and the second rigid transparent layer including a second interior surface facing the first interior surface;
first and second adhesive layers positioned on the first and second interior surfaces, respectively, of the first and second rigid transparent layers;
first and second display circuits attached to the first and second rigid transparent layers via the first and second adhesive layers, respectively, the first display circuit including a first array of electronically-activated light elements, and the second display circuit including a second array of electronically-activated light elements; and
a flexible substrate with opposing first and second surfaces, the first surface mounting thereon the first display circuit, and the second surface mounting thereon the second display circuit, the flexible substrate defining therethrough a plurality of apertures interleaved with the first and second arrays of electronically-activated light elements.

2. The electronic display device of claim 1, wherein the plurality of apertures includes a plurality of through holes and/or a plurality of slots.

3. The electronic display device of claim 1, wherein the apertures have a predetermined size, geometry, concentration and/or arrangement configured to provide a visible transparency of at least approximately 20% to 50%.

4. The electronic display device of claim 1, wherein the plurality of apertures includes a plurality of circular through holes with a diameter of approximately 1 mm to 6 mm and a pitch of approximately 2 mm to 10 mm.

5. The electronic display device of claim 1, wherein the plurality of apertures includes a plurality of square through holes with a width of approximately 1 mm to 12 mm and a pitch of approximately 5 mm to 20 mm.

6. The electronic display device of claim 1, wherein the plurality of apertures includes a plurality of polygonal through holes with a major dimension of approximately 2 mm to 11 mm and a pitch of approximately 4 mm to 14 mm.

7. The electronic display device of claim 1, wherein the flexible substrate includes a bendable glass panel.

8. The electronic display device of claim 1, wherein the flexible substrate includes an elastic thermoplastic resin panel.

9. The electronic display device of claim 1, further comprising first and second polyamide insulating layers covering the first and second display circuits, respectively.

10. The electronic display device of claim 1, wherein the first and second arrays of electronically-activated light elements each includes a plurality of light emitting diode (LED) cells and/or a plurality of liquid crystal display (LCD) cells.

11. The electronic display device of claim 1, wherein the first and second adhesive layers each includes a polyvinyl butyral (PVB) material.

12. The electronic display device of claim 1, wherein the first and second rigid transparent layers each includes a glass panel.

13. A motor vehicle comprising:
a vehicle body defining a passenger compartment with a pair of A-pillars partially defining a front window frame;
a plurality of road wheels rotatably attached to the vehicle body; and
a front windshield unit with integral electronic display device mounted between the A-pillars within the front window frame, the front windshield unit comprising:
first and second rigid glass layers juxtaposed in opposing spaced relation, the first rigid glass layer including a first interior surface, and the second rigid glass layer including a second interior surface facing the first interior surface;
first and second adhesive layers positioned on the first and second interior surfaces, respectively, of the first and second rigid glass layers;
first and second display circuits attached to the first and second rigid glass layers via the first and second adhesive layers, respectively, the first display circuit including a first array of electronically-activated LED elements, and the second display circuit including a second array of electronically-activated LED elements; and
a flexible substrate with opposing first and second surfaces, the first surface mounting thereon the first display circuit, and the second surface mounting thereon the second display circuit, the flexible substrate defining therethrough a plurality of apertures interleaved with the first and second arrays of electronically-activated LED elements.

14. A method of assembling an electronic display device, the method comprising:
providing first and second rigid transparent layers juxtaposed in opposing spaced relation with each other, the first rigid transparent layer including a first interior surface, and the second rigid transparent layer including a second interior surface facing the first interior surface;
applying a first adhesive layer on the first interior surface of the first rigid transparent layer;
applying a second adhesive layer on the second interior surface of the second rigid transparent layer;
attaching a first display circuit to the first rigid transparent layer via the first adhesive layer, the first display circuit including a first array of electronically-activated light elements;
attaching a second display circuit to the second rigid transparent layer via the second adhesive layer, the second display circuit including a second array of electronically-activated light elements; and
mounting the first and second display circuits to opposing first and second surfaces, respectively, of a flexible substrate, the flexible substrate defining therethrough a plurality of apertures interleaved with the first and second arrays of electronically-activated light elements.

15. The method of claim 14, wherein the plurality of apertures includes a plurality of through holes and/or a plurality of slots having a predetermined size, geometry, and pitch configured to provide a visible transparency of at least approximately 20% to 50%.

16. The method of claim 14, wherein the plurality of apertures includes a plurality of circular through holes with a diameter of approximately 1 mm to 6 mm and a pitch of approximately 2 mm to 10 mm.

17. The method of claim 14, wherein the plurality of apertures includes a plurality of square through holes with a width of approximately 1 mm to 12 mm and a pitch of approximately 5 mm to 20 mm.

18. The method of claim 14, wherein the plurality of apertures includes a plurality of polygonal through holes with a major dimension of approximately 2 mm to 11 mm and a pitch of approximately 4 mm to 14 mm.

19. The method of claim 14, wherein the flexible substrate includes a bendable glass panel or an elastic thermoplastic resin panel.

20. The method of claim 14, further comprising covering the first and second display circuits with first and second polyamide insulating layers, respectively.
